(19) United States
(12) Patent Application Publication
(10) Pub. No.: US 2025/0214172 A1
(43) Pub. Date: Jul. 3, 2025

(54) SUBSTRATE PROCESSING APPARATUS

(71) Applicant: SEMES CO., LTD., Cheonan-si (KR)

(72) Inventors: Young Dae CHUNG, Incheon (KR); Tae Shin KIM, Suwon-si (KR); Seryeyohan CHO, Daejeon (KR); Hyeong Soo PARK, Yongin-si (KR); Ki Hoon CHOI, Cheonan-si (KR)

(73) Assignee: SEMES CO., LTD., Cheonan-si (KR)

(21) Appl. No.: 19/001,696

(22) Filed: Dec. 26, 2024

(30) Foreign Application Priority Data
Dec. 27, 2023 (KR) 10-2023-0192692

(51) Int. Cl. B23K 26/03; B23K 26/067

(52) U.S. Cl. CPC B23K 26/032; B23K 26/067

(57) ABSTRACT

The present invention provides a substrate processing apparatus. The substrate processing apparatus includes: a supporting unit supporting a substrate; a laser emission assembly emitting a laser to the substrate, wherein the laser emission assembly includes: a laser source generating a laser; and a plurality of laser emission modules, the laser emission modules each include: a light modulation unit modulating distribution of a laser generated by the laser source; and an imaging unit adjusting and emitting the laser modulated by the light modulation unit to the substrate to correspond to an area to which the laser is emitted, an entire region that needs to be heated on the substrate is composed of a plurality of unit emission regions, and the plurality of laser emission modules are arranged to be able to emit the laser respectively to the different unit emission regions of the substrate supported on the supporting unit.

### CROSS-REFERENCE TO RELATED APPLICATIONS

This application claims priority to and the benefit of Korean Patent Application No. 10-2023-0192692 filed in the Korean Intellectual Property Office on Dec. 27, 2023, the entire contents of which are incorporated herein by reference.

### TECHNICAL FIELD

The present invention relates to a substrate processing apparatus and, in more detail, an apparatus for processing a substrate by emitting a laser.

### BACKGROUND ART

In order to manufacture a semiconductor device, various processes such as photographing, etching, ashing, ion injection, and thin film deposition are performed on a substrate such as a wafer. Various processing liquids and processing gases are used in the processes. Further, a drying process is performed on a substrate to remove processing liquid, which is used to process the substrate, from the substrate.

Recently, the critical dimension of semiconductor circuits has been miniaturized, so Extreme Ultra-Violet (EUV) light is used as an exposure light source. Further, in accordance with the characteristic of EUV light with a short wavelength, a method of modulating light L using a light modulation device such as a Digital Micro-mirror Device (hereafter, referred to as a DMD), forming an emission pattern, and emitting the emission pattern to a mask or a wafer is used.

Meanwhile, it is possible to heat a specific region of a substrate by emitting light to the upper surface of a substrate having a liquid film formed by chemical liquid. The entire pattern on a substrate is etched by chemical liquid and a specific region to which light is emitted can be more etched because it is heated. The degree of etching depends on the amount of heat transmitted by light per unit time and a DMD can form emission patterns having various shapes, so it is possible to control etching for a substrate M in various ways.

However, due to the limitation in physical property of the DMD, there is a limit to the output of light that is emitted to each of mirrors of the DMD. Accordingly, when it is required to heat a wide region of a substrate using high-power light, the number of micromirrors that are applied to heat unit areas of the substrate increases and the emission region in which the DMD can heat the substrate per unit time relatively decreases, so a method of emitting light L to the entire region of a substrate that needs to be heated by sequentially emitting light to partial regions is employed. This method has a problem that the process time increases and the throughput decreases.

### SUMMARY OF THE INVENTION

An objective of the present invention is to provide a substrate processing apparatus that can effectively process substrates.

Further, an objective of the present invention is to provide a substrate processing apparatus that can effectively adjust the critical dimension of a pattern formed on a substrate.

Further, an objective of the present invention is to provide a substrate processing apparatus that can simultaneously emit light to a wide region of a substrate that needs to be heated.

The objectives of the present invention are not limited thereto and other objectives not stated herein may be clearly understood by those skilled in the art from the following description.

The present invention provides a substrate processing apparatus. The substrate processing apparatus includes: a supporting unit supporting a substrate; a laser emission assembly emitting a laser to the substrate, wherein the laser emission assembly includes: a laser source generating a laser; and a plurality of laser emission modules, the laser emission modules each include: a light modulation unit modulating distribution of a laser generated by the laser source; and an imaging unit adjusting and emitting the laser modulated by the light modulation unit to the substrate to correspond to an area to which the laser is emitted, an entire region that needs to be heated on the substrate is composed of a plurality of unit emission regions, and the plurality of laser emission modules are arranged to be able to emit the laser respectively to the different unit emission regions of the substrate supported on the supporting unit.

In an embodiment, the laser emission assembly may be configured by arranging the plurality of laser emission modules such that the unit emission regions respectively corresponding to the plurality of laser emission modules are continued in a line to form an emission region.

In an embodiment, the laser emission assembly may be configured by arranging the plurality of laser emission modules such that the emission regions are continued in one or more lines to form an entire emission region.

In an embodiment, the entire emission region to which the laser is emitted on the substrate from the laser emission assembly may be the entire region that needs to be heated on the substrate.

In an embodiment, the laser emission assembly may further includes a control unit, wherein the control unit may control the laser emission assembly to emit the laser to the entire region of the substrate by emitting the laser to corresponding unit emission regions through the plurality of laser emission modules, respectively.

In an embodiment, the laser emission assembly may include: a first emission module disposed in an edge region and comprising one or more of the laser emission module; a second emission module disposed in another edge region and comprising one or more of the laser emission module; and a third emission module disposed in a center region and comprising one or more of the laser emission module, and the third emission module may be disposed at a height different from the first emission module and the second emission module.

In an embodiment, the first emission module, the second emission module, and the third emission module each may have a frame surrounding the light modulation unit, and the frame of the third emission module and the frame of the first emission module or the second emission module may partially overlap each other when seen from above.

In an embodiment, the laser emission assembly may further includes a control unit, and the control unit may perform control such that the plurality of laser emission modules emit the laser to corresponding unit emission regions, respectively, on the substrate, relative positions of the substrate supported on the supporting unit and the laser emission modules are changed by horizontally moving any one of the supporting unit and the laser emission assembly, and the plurality of laser emission modules can emit the laser to the entire region of the substrate through the horizontal movement.

In an embodiment, the laser emission assembly may further include: an actuator rotating the supporting unit; and a control unit, wherein the control unit may perform control such that the laser emission assembly emits the laser to a first region of the substrate by emitting the laser to corresponding unit emission regions of the substrate through the plurality of laser emission modules, respectively, and such that the laser emission assembly emits the laser to a second region on the substrate by rotating the supporting unit, the first region and the second region each may be a region corresponding to a half of the entire region of the substrate, and the plurality of laser emission modules can emit the laser to the entire region of the substrate through the rotation.

In an embodiment, the substrate processing apparatus may further include a liquid supply unit supplying liquid to a substrate supported on the supporting unit.

In an embodiment, the laser emission assembly may further include a laser transmission member transmitting the laser generated by the laser source to the laser emission modules.

In an embodiment, the laser emission assembly may further include a beam splitter splitting the laser generated by the laser source, and the laser split by the beam splitter may be transmitted to the laser emission modules through the laser transmission member.

In an embodiment, the laser emission assembly may further include a beam shaper converting the type of the laser generated by the laser source, and the beam shaper may change the type of the laser transmitted through the laser transmission member and transmit the laser with the changed type to the light modulation unit.

In an embodiment, the substrate may be a photomask or a wafer.

In an embodiment, the light modulation unit may further include a Digital Micro-mirror Device (DMD) that is a light modulation device, and the DMD may include: micromirrors provided to be rotatable; and a board substrate on which the micromirrors are installed.

Further, the present invention provides a substrate processing apparatus. In an embodiment, the substrate processing apparatus includes: a supporting unit supporting a substrate; and a laser emission assembly emitting a laser to the substrate, wherein the laser emission assembly includes: a laser source generating a laser; a plurality of laser emission modules; and a laser transmission member transmitting the laser generated by the laser source to the laser emission modules, the laser emission modules each include: a Digital Micro-mirror Device (DMD) unit modulating distribution of the laser generated by the laser source; and an imaging unit adjusting and emitting the laser modulated by the DMD to the substrate to correspond to an area to which the laser is emitted, wherein the DMD includes: micromirrors provided to be rotatable; and a device substrate on which the micromirrors are installed, an entire region that needs to be heated on the substrate is composed of a plurality of unit emission regions, and the plurality of laser emission modules are arranged to be able to emit the laser respectively to the different unit emission regions of the substrate supported on the supporting unit.

In an embodiment, the laser emission assembly may be configured by arranging the plurality of laser emission modules such that the unit emission regions respectively corresponding to the plurality of laser emission modules are continued in a line to form an emission region and the emission regions are continued in one or more lines to form an entire emission region.

In an embodiment, the laser emission assembly may include: a first emission module disposed in an edge region and comprising one or more of the laser emission module; a second emission module disposed in another edge region and comprising one or more of the laser emission module; and a third emission module disposed in a center region and comprising one or more of the laser emission module, the third emission module may be disposed at a height different from the first emission module and the second emission module, and the laser emission assembly may be controlled to emit the laser to the entire region of the substrate by emitting the laser to corresponding emission regions through the first emission module, the second emission module, and the third emission module, respectively.

Further, the present invention provides a substrate processing apparatus. In an embodiment, the substrate processing apparatus includes: a supporting unit supporting a substrate; a laser emission assembly emitting a laser to the substrate; and a control unit, wherein the laser emission assembly includes: a laser source generating a laser; a plurality of laser emission modules; and a laser transmission member transmitting the laser generated by the laser source to the laser emission modules, wherein the laser emission modules each include: a Digital Micro-mirror Device (DMD) unit modulating distribution of the laser generated by the laser source; and an imaging unit adjusting and emitting the laser modulated by the DMD to the substrate to correspond to an area to which the laser is emitted, wherein the DMD includes: micromirrors provided to be rotatable; and a device substrate on which the micromirrors are installed, an entire region that needs to be heated on the substrate is composed of a plurality of unit emission regions, the plurality of laser emission modules are arranged to be able to emit the laser respectively to the different unit emission regions of the substrate supported on the supporting unit, the unit emission regions respectively corresponding to the plurality of laser emission modules are continued in a line to form an emission region, the emission regions are continued in one or more lines to form an entire emission region, the entire emission region is the entire region that needs to be heated on the substrate, and the control unit controls the laser emission assembly to emit the laser to the entire region of the substrate by emitting the laser to corresponding unit emission regions through the plurality of laser emission modules, respectively.

In an embodiment, the laser emission assembly may include: a first emission module disposed in an edge region and comprising one or more of the laser emission module; a second emission module disposed in another edge region and comprising one or more of the laser emission module; and a third emission module disposed in a center region and comprising one or more of the laser emission module, and the third emission module may be disposed at a height different from the first emission module and the second emission module.

According to an embodiment of the present invention, it is possible to effectively process a substrate.

Further, according to an embodiment of the present invention, it is possible to effectively adjust the critical dimension of a pattern formed on a substrate.

Further, according to an embodiment of the present invention, it is possible to simultaneously emit light to a wide region of a substrate that needs to be heated.

Effects of the present invention are not limited to those described above and effects not stated above will be clearly understood to those skilled in the art from the specification and the accompanying drawings.

### BRIEF DESCRIPTION OF THE DRAWINGS

FIG. 1 is a plan view schematically showing a substrate processing apparatus according to an embodiment of the present invention.

FIG. 2 is a view schematically showing the appearance of a substrate that is processed in the liquid processing chamber of FIG. 1.

FIG. 3 is a view schematically showing an embodiment of the liquid processing chamber of FIG. 1.

FIG. 4 is a view schematically showing the configuration of the laser emission module of FIG. 3.

FIG. 5 is a graph showing distribution of light that is output from a laser source and FIG. 6 is a graph showing distribution of light that has passed through a beam shaper.

FIG. 7 is a view schematically showing the appearance of a light modulation device.

FIG. 8 is a view showing that light is output from a light modulation device.

FIG. 9 is a view showing that light output from the light modulation device is removed at an optical dumber.

FIG. 10 is a view for explaining the principle that light is removed at an optical dumper.

FIG. 11 is a view for explaining an emission pattern of light that is output from a light modulation unit.

FIG. 12 shows an emission region formed on a substrate when a laser emission assembly emits light to the substrate of FIG. 2.

FIG. 13 is a perspective view showing the appearance of a laser emission assembly according to an embodiment of the present invention.

FIG. 14 shows an emission region to which light is emitted on a substrate by the first emission module of FIG. 13.

FIG. 15 shows an emission region to which light is emitted on a substrate by the laser emission assembly of FIG. 13.

FIG. 16 is a perspective view showing the appearance of a laser emission assembly according to another embodiment of the present invention and FIG. 17 shows an emission region to which light is emitted on a substrate by the laser emission assembly of FIG. 16.

FIG. 18 shows another embodiment in which the laser emission assembly of FIG. 16 emits light to a substrate.

FIG. 19 is a perspective view showing the appearance of a laser emission assembly according to another embodiment of the present invention and FIG. 20 shows an emission region to which light is emitted on a substrate by the laser emission assembly of FIG. 19.

FIG. 21 briefly shows a configuration in which a laser source and a laser transmission member transmit light to a laser emission module in accordance with another embodiment of the present invention.

FIG. 22 is a flowchart showing a substrate processing method according to an embodiment of the present disclosure.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

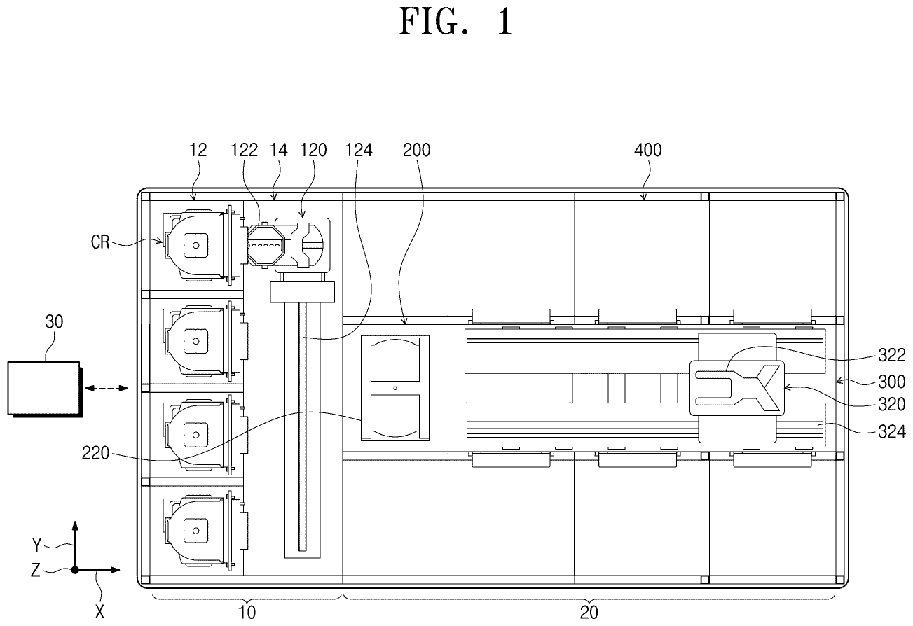

Hereafter, embodiments of the present invention are described with reference to FIG. 1 to FIG. 20.

FIG. 1 is a plan view schematically showing a substrate processing apparatus according to an embodiment of the present invention.

Referring to FIG. 1, a substrate processing apparatus includes an index module 10, a processing module 20, and a control unit 30. When seen from above, the index module 10 and the processing module 20 are disposed in one direction. Hereafter, the direction in which the index module 10 and the processing module 20 are arranged is referred to as a first direction X, a direction perpendicular to the first direction X when seen from above is referred to as a second direction Y, and a direction perpendicular to both of the first direction X and the second direction Y is referred to as a third direction Z.

The index module 10 transfers substrates M to the processing module 20 from containers CR accommodating the substrates M and puts the substrates M processed at the processing module 20 into the containers CR. The longitudinal direction of the index module 10 is provided in the second direction Y. The index module 10 has a load port 12 and an index frame 14. The load port 12 is positioned at the opposite side to the processing module 20 with the index frame 14 therebetween. The containers CR accommodating substrates M are placed in the load port 12. A plurality of load ports 12 may be provided and the plurality of load ports 12 may be disposed in the second direction Y.

The container CR may be a container for sealing such as a Front Open Unified Pod (FOUP). The container CR may be placed in the load port 12 by a worker or a conveying device (not shown) such as an overhead transfer, an overhead conveyor, or an automatic guided vehicle.

An index robot 120 is provided at the index frame 14. A guide rail 124 of which the longitudinal direction is provided in the second direction Y is provided in the index frame 14 and the index robot 120 may be provided to be movable on the guide rail 124. The index robot 120 includes a hand 122 on which substrates M are placed and the hand 122 may be provided to be able to move forward and backward, rotate about the third direction Z, and move in the third direction Z. A plurality of hands 122 may be provided to be spaced apart from each other in the up-down direction and the hands 122 can move forward and backward independently from each other.

The control unit 30 can control the components of the substrate processing apparatus. The control unit 30 may include: a process controller that is a microprocessor (computer) that performs control of the operation of the substrate processing apparatus; a user interface that is a keyboard through which an operator performs command input operation, etc. to manage the substrate processing apparatus, a display that visualizes and displays the operation situation of the substrate processing apparatus, etc.; and a memory that stores a control program for performing processing, which is performed in the substrate processing apparatus, under control of the process controller, a program for performing processing on each component in accordance with various data and processing conditions, that is, a processing recipe. Further, the user interface and the memory may be connected to the process controller. The processing recipe may be stored in a memory medium of the memory unit and the memory medium may be a hard disk and may be a portable disc such as a CD-ROM and a DVD, and a semiconductor memory such as a flash memory.

The control unit 30 can control the substrate processing apparatus to be able to perform the substrate processing method to be described below. For example, the control unit 30 can control the components provided in a liquid processing chamber 400 to be able to perform the substrate processing method to be described below.

The processing module 20 includes a buffer unit 200, a transfer chamber 300, and a liquid processing chamber 400. The buffer unit 200 provides a space in which substrates M that are loaded into the processing module 20 and substrates M that are unloaded from the processing module 20 temporarily stay. The liquid processing chamber 400 performs a liquid processing process of liquid processing on substrates M by supplying liquid onto the substrates M. The transfer chamber 300 transfers substrates M between the buffer unit 200 and the liquid processing chamber 400.

The longitudinal direction of the transfer chamber 300 may be provided in the first direction X. The buffer unit 200 may be disposed between the index module 10 and the transfer chamber 300. The liquid processing chamber 400 may be disposed on a side of the transfer chamber 300. The liquid processing chamber 400 and the transfer chamber 300 may be disposed in the second direction Y. The buffer unit 200 may be positioned at an end of the transfer chamber 300.

According to an example, the liquid processing chambers 400 may be disposed at both sides of the transfer chamber 300. The liquid processing chambers 400 may be provided in an array of A×B (A and B are each a natural number of 1 or more) in the first direction X and the third direction Z, respectively, at a side of the transfer chamber 300.

The transfer chamber 300 has a transfer robot 320. A guide rail 324 of which the longitudinal direction is provided in the first direction X is provided in the transfer chamber 300 and the transfer robot 320 may be provided to be movable on the guide rail 324. The transfer robot 320 includes a hand 322 on which substrates M are placed and the hand 322 may be provided to be able to move forward and backward, rotate about the third direction Z, and move in the third direction Z. A plurality of hands 322 may be provided to be spaced apart from each other in the up-down direction and the hands 322 can move forward and backward independently from each other.

The buffer unit 200 has a plurality of buffers 220 on which substrates M are placed. The buffers 220 may be disposed to be spaced apart from each other in the third direction Z. The buffer unit 200 is open on the front face and the rear face. The front face is a surface that faces the index module 10 and the rear face is a surface that faces the transfer chamber 300. The index robot 120 can approach the buffer unit 200 through a front face and the transfer robot 320 can approach the buffer unit 200 through a rear face.

Hereafter, substrates M that are processed in the liquid processing chamber 400 are described in detail.

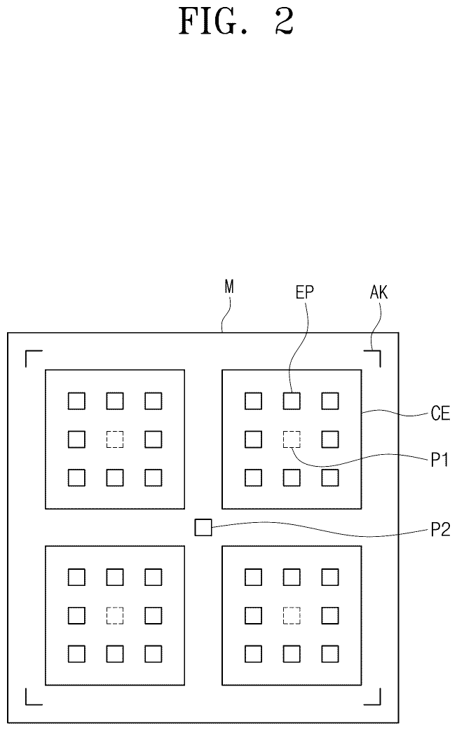

FIG. 2 is a view schematically showing the appearance of a substrate that is processed in the liquid processing chamber of FIG. 1.

Referring to FIG. 2, a processing target that is processed in the liquid processing chamber 400 may be any one substrate of a wafer, a glass, and a photomask. Hereafter, it is exemplarily described that the substrate M that is processed in the liquid processing chamber 400 is a photomask that is a ‘frame’ that is used in an exposure process.

The substrate M may have a rectangular shape. The substrate M may be a mask that is a ‘frame’ that is used in an exposure process. At least one or more reference marks AK may be formed on the substrate M. For example, a plurality of reference marks AK may be formed at the corner regions of the substrate M, respectively. The reference marks AK may be marks that are called align keys and used to align the substrate M. Further, the reference marks AK may be marks that are used to derive position information of the substrate M. For example, a vision sensor (not shown) such as a camera may be provided in the liquid processing chamber 400, the vision sensor obtains an image by photographing the reference marks AK, and the control unit 30 can detect the position and direction of the substrate M by analyzing the images including the reference marks AK. Further, the reference marks AK may be marks that are used to find out position of the substrate M when the substrate M is transferred.

A cell CE may be formed on the substrate M. At least one or more cells CE, for example, a plurality of cells CE may be formed. A plurality of patterns may be formed in each cell CE. The patterns formed in each cell CE may be defined as one pattern group. The patterns formed in the cell CE may include exposure patterns EP and a first pattern P1. The exposure patterns EP can be used to form an actual pattern on the substrate M. Further, the first pattern P1 may be a pattern that represents exposure patterns EP formed in one cell CE. Further, when a plurality of cells CE is provided, a plurality of first patterns P1 may be provided. Further, a plurality of first patterns P1 may be formed in one cell CE. The first pattern P1 may have a shape that is a combination of portions of exposure patterns EP. The first pattern P1 may be referred to as a monitoring pattern. Further, the first pattern P1 may be referred to as a critical dimension monitoring macro.

When a worker inspects the first pattern P1 through a scanning electron microscope (SEM), it is possible to presume whether the shapes of the exposure patterns EP formed in one cell CE are good or poor. Further, the first pattern P1 may be a pattern for inspection. Further, the first pattern P1 may be any one pattern of exposure patterns EP actually participating in an exposure process. Further, the first pattern P1 may be a pattern for inspection and simultaneously an exposure pattern actually participating in exposure.

A second pattern P2 may be a pattern that represents exposure patterns EP formed on the entire substrate M. For example, the second pattern P2 may have a shape that is a combination of portions of first patterns P1.

When a worker inspects the second pattern P2 through a scanning electron microscope (SEM), it is possible to presume whether the shapes of the exposure patterns EP formed in one substrate are good or poor. Further, the second pattern P2 may be a pattern for inspection. Further, the second pattern P2 may be a pattern that actually does not participate in an exposure process. The second pattern P2 may be referred to as an anchor pattern.

Hereafter, a substrate processing apparatus that is provided at the liquid processing chamber 400 is described in detail. In substrates M that are loaded into the liquid processing chamber 400, it may be required to adjust the critical dimension of at least one or more of a first pattern P1, a second pattern P2, and exposure patterns EP.

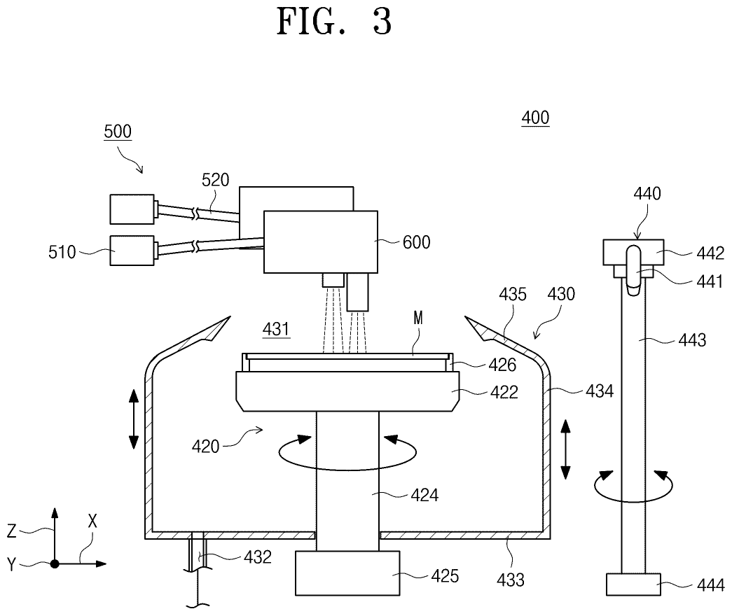

FIG. 3 is a view schematically showing an embodiment of the liquid processing chamber of FIG. 1. Referring to FIG. 3, the liquid processing chamber 400 includes a supporting unit 420, a bowl 430, a chemical liquid supply unit 440, and a laser emission assembly 500.

The supporting unit 420 can support a substrate M in a processing space 431 defined by the bowl 430 to be described below. The supporting unit 420 can support a substrate M. The supporting unit 420 can rotate the substrate M.

The supporting unit 420 may include a chuck 422, a supporting shaft 424, an actuating member 425, and a supporting pin 426. The supporting pin 426 may be installed on the chuck 422. The chuck 422 may have a plate shape having a predetermined thickness. The supporting shaft 424 may be coupled to the lower portion of the chuck 422. The supporting shaft 424 may be a hollow shaft. Further, the supporting shaft 424 can be rotated by the actuating member 425. The actuating member 425 may be a hollow motor. When the actuating member 425 rotates the supporting shaft 424, the chuck 422 coupled to the supporting shaft 424 can be rotated. The substrate M placed on the supporting pin 426 installed on the chuck 233 can also be rotated by rotation of the chuck 422.

The supporting pin 426 can support a substrate M. The supporting pin 426 may have a substantially circular shape when seen from above. Further, when seen from above, the supporting pin 426 may have a shape recessed downward at the portions corresponding to the corner regions of a substrate M. That is, the supporting pin 426 may include a first surface supporting the lower portions of the corner regions of a substrate M and a second surface facing the sides of the corner regions of the substrate M to be able to restrict lateral movement of the substrate M when the substrate M is rotated. At least one or more supporting pins 426 may be provided. A plurality of supporting pins 426 may be provided. The supporting pins 426 may be provided in the number corresponding to the number of the corner regions of a substrate M having a rectangular shape. The supporting pins 426 can space the bottom surface of a substrate M and the top surface of the chuck 422 by supporting the substrate M.

The bowl 430 may have a cylindrical shape with open top. The bowl 430 can define the processing space 431. A substrate M can be liquid-processed and heated in the processing space 431. The bowl 430 can prevent processing liquid that is supplied to a substrate M from being scattered and transmitted to the chemical liquid supply unit 440 and the laser emission assembly 500.

The bowl 430 may include a bottom portion 433, a vertical portion 434, and an inclined portion 435. An opening in which the supporting shaft 424 can be inserted may be formed at the bottom portion 433 when seen from above. The vertical portion 434 may extend in the third direction Z from the bottom portion 433. The inclined portion 435 may extend at an angle upward from the vertical portion 434. For example, the inclined portion 435 may extend at an angle toward a substrate M supported on the supporting unit 420. A discharge hole 432 that can discharge processing liquid, which is supplied from the chemical liquid supply unit 440, to the outside may be formed through the bottom portion 433.

Further, the bowl 430 is coupled to an elevation member (not shown), so the position thereof can be changed in the third direction Z. The elevation member may be an actuating device that moves up and down the bowl 430. The elevation member can move up the bowl 430 while liquid processing and/or heating processing is performed on a substrate M, and can move down the bowl 430 when a substrate M is loaded into the liquid processing chamber 400 or a substrate M is unloaded from the processing chamber 400.

The chemical liquid supply unit 440 can supply chemical liquid for performing liquid processing on a substrate M. The liquid supply unit 440 can supply chemical liquid to a substrate M supported on the supporting unit 420. The chemical liquid may be an etching solution or a rinse solution. The etching solution may be a chemical. The etching solution can etch the pattern formed on a substrate M. The etching solution may be referred to as an etchant. The rinse solution can wash a substrate M. The rinse solution may be provided as well-known chemical liquid.

The chemical liquid supply unit 440 may include a nozzle 441, a fixing body 442, a rotary shaft 443, and a rotary member 444.

The nozzle 441 can supply processing liquid to a substrate M supported on the supporting unit 420. A first end of the nozzle 441 may be connected to the fixing body 442 and a second end may extend toward a substrate M from the fixing body 442. The nozzle 441 may extend in the first direction X from the fixing body 442. Further, the second end of the nozzle 441 may bend at an angle and extend toward a substrate M supported on the supporting unit 420.

If necessary, a plurality of nozzles 441 may be provided. Any one of the nozzles 441 may be a nozzle that discharges the etching solution described above and another one of the nozzles 441 may be a nozzle that discharges the rinse solution described above.

The body 442 can fix and support the nozzle 441. The body 442 may be connected with the rotary shaft 443 that is rotated around the third direction Z by the rotary member 444. When the rotary member 444 rotates the rotary shaft 443, the body 442 can be rotated around the third direction Z. Accordingly, the outlet of the nozzle 441 can be moved between a liquid supply position that is a position where processing liquid is supplied to a substrate M and a standby position that is a position where processing liquid is not supplied to a substrate M.

The laser emission assembly 500 can emit a laser to a substrate M. The laser emission assembly 500 can adjust the critical dimension of the pattern formed on a substrate M by emitting a laser to the substrate M with the pattern formed on the top surface, by a chemical liquid (e.g., an etching solution) that is supplied by the chemical liquid supply unit 440. The temperature of the region of a substrate M to which the laser emitted by the laser emission assembly 500 is emitted can be increased. Accordingly, the region emitted with a laser can be relatively more etched and the region not emitted with a laser can be relatively less etched. In this way, it is possible to adjust the critical dimension of the pattern formed on a substrate M.

The laser emission assembly 500 includes a laser source 410, a laser transmission member 520, and a plurality of laser emission modules 600.

The laser source 510 can generate light L. The laser source 510 can generate light L having straightness. The light L generated by the laser source 510 can be emitted to a substrate M and can heat the substrate M. The light L may be a laser beam, a fiber laser, a laser diode, or the like. Hereafter, it is exemplarily described that the light L is a laser. The laser source 510 may have power of a range within 20 W per unit area (cm²). When the laser source 510 has power of a range within 20 W per unit area (cm²), a light modulation device 642 to be described below can be appropriately driven without being damaged.

The laser transmission member 520 transmits the light L generated by the laser source 510 to the laser emission modules 600. According to an example, the laser transmission member 520 may be an optical fiber.

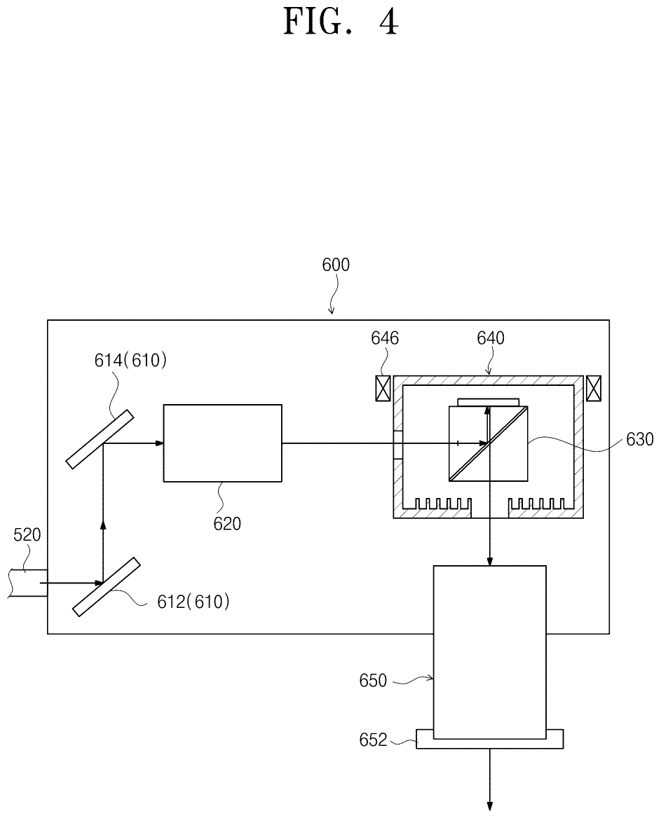

FIG. 4 is a view schematically showing the configuration of the laser emission module of FIG. 3.

The laser emission module 600 includes a mirror 610, a beam shaper 620, a prism optical device 630, a light modulation unit 640, and an imaging unit 650.

The mirror 610 reflects and transmits light L traveling into the laser emission module 600 through the laser transmission member 520 to the beam shaper 620. The mirror 610 may include a plurality of mirrors to appropriately reflect the path of the light L. For example, the mirror 610 may include a first mirror 612 and a second mirror 614.

The beam shaper 620 can change the type of the light that is output from the laser source 510.

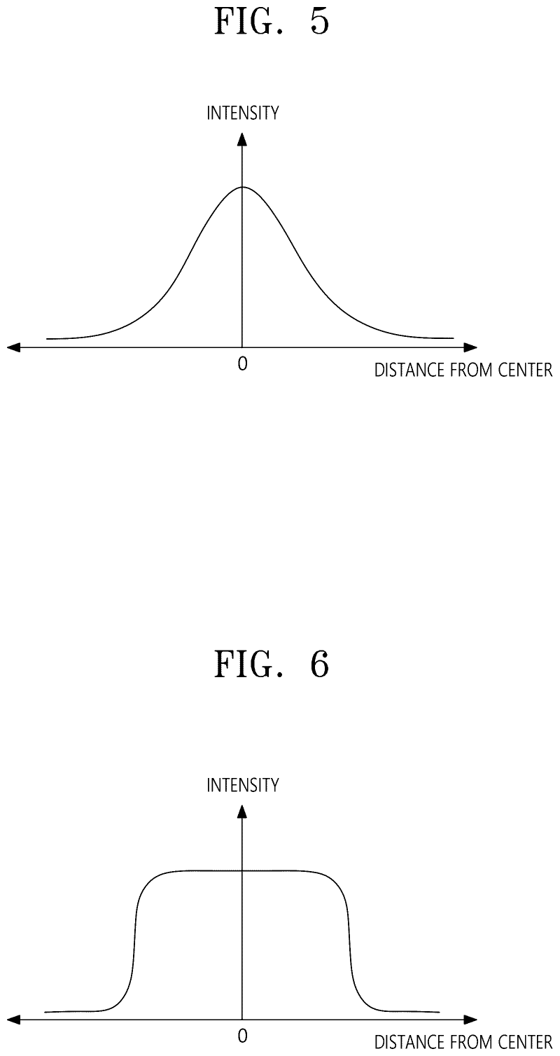

FIG. 5 is a graph showing distribution of light that is output from a laser source and FIG. 6 is a graph showing distribution of light that has passed through a beam shaper.

Referring to FIG. 4 to FIG. 6, the light L that is output from the laser source 510, as shown in FIG. 6, may have a Gaussian type in which the strength distribution has Gaussian distribution. In more detail, the intensity of the light L that is output from the laser source 510 may be high at the center of the light L and the intensity (strength) thereof may gradually decrease as it goes away from the center of the light L (see FIG. 5). Accordingly, when the light L that is output from the laser source 510 is emitted to a substrate M, the region close to the center of the light L can be more heated and the region close to the edge of the light L can be less heated. Accordingly, in the laser emission module 600 according to an embodiment of the present invention, the beam shaper 620 may be disposed on the traveling path of the light L output from the laser source 510. The beam shaper 620 can convert Gaussian-type light L that is output from the laser source 510 into flat top-type light L. The light L that is output from the laser source 510 can be converted into a flat top type having flat top distribution, in which the intensity (luminance) distribution is relatively uniform, through the beam shaper 620 (see FIG. 6).

Referring to FIG. 4 again, the light L that has passed through the beam shaper 620 can be transmitted to the prism optical device 630.

The prism optical device 630 can reflect the light L that has passed through the beam shaper 620 back to the light modulation unit 640. The light L transmitted to the light modulation unit 640 can be modulated at the light modulation unit 640 and then output. The light L modulated and output from the light modulation unit 640 can be transmitted to the imaging unit 650 through the prism optical device 630.

The light modulation unit 640 can modulate the transmitted light L. The light modulation unit 640 may include a light modulation device 642, an optical dumper 644, and a cooling device 646.

The light modulation device 642 can modulate the distribution of the light L that is generated by the laser source 510. In this case, modulation of the distribution of the light L may be forming distribution of light L corresponding to the emission pattern of light L to be emitted to a substrate M.

The light modulation device 642 may be a Digital Micro-mirror Device (DMD).

That is, the light modulation unit 640 may be a DMD unit including a Digital Micro-mirror Device (DMD).

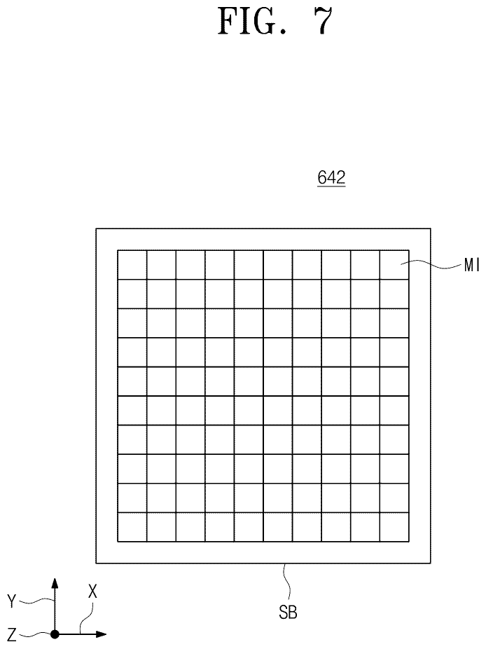

FIG. 7 is a view schematically showing the appearance of a light modulation device. The light modulation device 642 may include a board substrate SB and a plurality of micromirrors MI. Electrodes corresponding to the plurality of micromirrors MI, respectively, may be installed on the board substrate SB. The control unit 30 can transmit a digital signal of “0” or “1” to the electrodes installed on the board substrate SB. The micromirrors MI may be configured to be rotatable. The micromirrors MI can be configured to be rotatable around a direction that is parallel with a plane passing through the first direction X, the second direction Y, or the first direction X and the second direction Y. A micromirror MI corresponding to an electrode receiving a digital signal of “0” can become an Off state and a micromirror MI corresponding to an electrode receiving a digital signal of “1” can become an On state. A micromirror MI in the On state can emit light L to a substrate and light L reflected by a micromirror MI in the Off state may not be emitted to a substrate M.

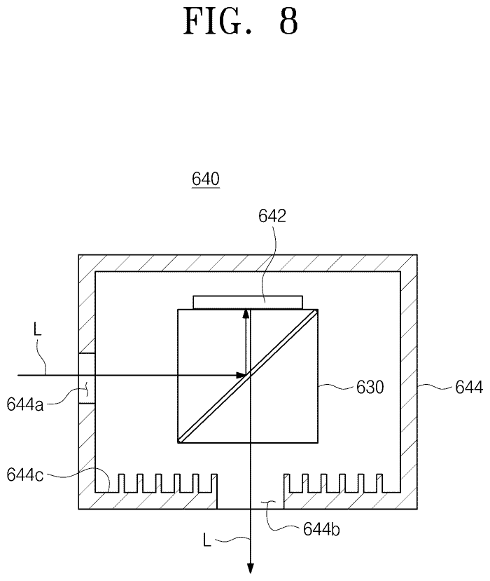

FIG. 8 is a view showing that light is output from a light modulation device. In FIG. 8, for the convenience of description, the traveling path of light that is reflected by any one micromirror MI of micromirrors MI is shown. Referring to FIG. 4, FIG. 7, and FIG. 8, a micromirror MI in the On state can transmit light to a substrate M through the imaging unit 650 to be described below.

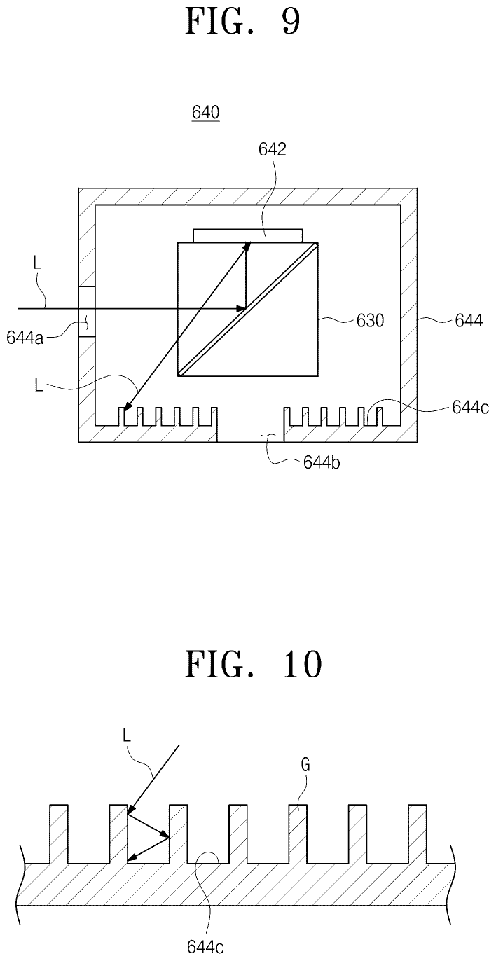

FIG. 9 is a view showing that light output from the light modulation device is removed at an optical dumber. In FIG. 9, for the convenience of description, the traveling path of light L that is reflected by any one micromirror MI of micromirrors MI is shown. Referring to FIG. 4, FIG. 7, and FIG. 9, a micromirror MI in the Off state may not transmit light L to a substrate M by reflecting the light L. In detail, micromirrors MI are configured to be rotatable, as described above. A micromirror MI in the Off state may make light not be transmitted to a substrate M by changing the traveling path of light L received from the laser source 510 by rotating. The light L that is discharged from the micromirror MI in the Off state may become extinct by being emitted to the inner surface of the optical dumber 644 without passing through a second hole 644b of the optical dumper 644.

FIG. 10 is a view for explaining the principle that light is removed at an optical dumper. Referring to FIG. 4 and FIG. 10, the optical dumber 644 may have a box shape. The optical dumber 644 may be made of a material that can remove light by absorbing it such as synthetic resin. The prism optical device 630 may be disposed in the internal space of the optical dumber 644. The light modulation device 642 may be disposed in the internal space of the optical dumber 644 or may be installed outside the optical dumber 644.

A first hole 644a and a second hole 644b may be formed at the optical dumber 644. The first hole 644a may be formed on a side of the optical dumber 644. The first hole 644a may be a hole through which light L generated by the laser source 510 and converted through the beam shaper 620 passes. The second hole 644b may be a hole through which light L modulated by the light modulation device 641 passes. The second hole 644b may be formed on the lower portion of the optical dumber 644.

Grooves G may be formed on the inner surface 644c of the optical dumber 644. The grooves G formed on the inner surface 644c of the optical dumber 644 may be configured to be able to absorb the light reflected by a micromirror MI in the Off state. In detail, when light L is transmitted to the grooves G, the light L can be removed by being reflected several times at the grooves G. The light L can be removed while being reflected several time at the grooves G and losing energy to the optical dumber 644. In FIG. 4 and FIG. 10, it is exemplarily shown that grooves G are formed only on the lower portion of the optical dumber 644, but the present invention is not limited thereto and grooves G may be formed on the entire inner surface 644c of the optical dumber 644.

Referring to FIG. 4 again, since the optical dumber 644 removes light L, the temperature of the optical dumber 644 can be increased. Accordingly, the light modulation unit 640 according to an embodiment of the present invention may include the cooling device 646 that cools the optical dumber 644. The cooling device 646 may be a fan that generates airflow for cooling the optical dumber 644.

The imaging unit 650 can emit light L that is modulated and output from the light modulation unit 640 and has passed through the prism optical device 630 to a substrate M by adjusting the light to correspond to an area to which the light L is emitted. The imaging unit 650 includes a plurality of lenses that can adjust the size of light L, and can adjust the profile of a laser that is emitted to a substrate M by increasing or decreasing the diameter of light L.

The imaging unit 650 may include a component that removes a noise pattern from refractive patterns output from the light modulation unit 640. For example, the imaging unit 650 may include a spatial filter.

The imaging unit 650 includes an emission lens 652. Light L that has been modulated and output from the light modulation unit 640 and has passed through the prism optical device 630 is adjusted by the imaging unit 650 and emitted to a substrate M through the emission lens 652.

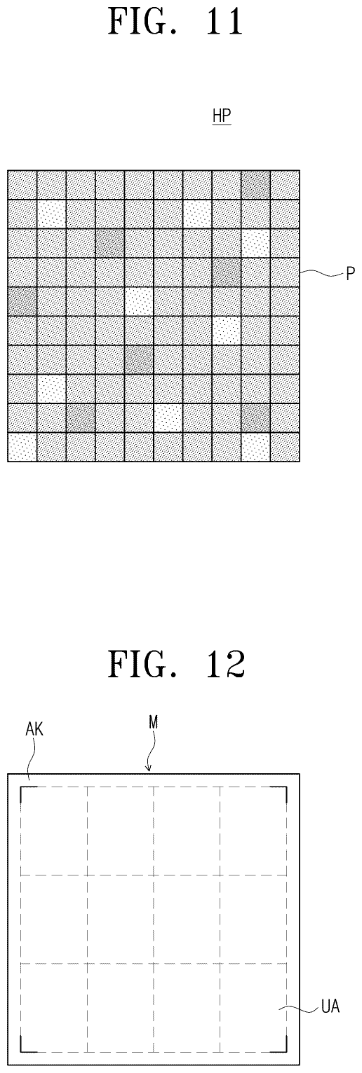

FIG. 11 is a view for explaining an emission pattern of light that is output from a light modulation unit. Referring to FIG. 4, FIG. 7, and FIG. 11, as described above, micromirrors MI can be changed between the On state and the Off state. The state changing of each micromirror MI between the On state and the Off state can be made within a very short time. By On-Off state changing of each micromirror MI, the light modulation unit 640 can form very various emission patterns HP. For example, in FIG. 11, the amount of heat that is transmitted to a substrate M per unit time by light L reflected by each micromirror MI for unit time (e.g., 1 second) is shown. The emission pattern HP may be composed of a plurality of patterns P corresponding to micromirrors MI, respectively. In order to increase the amount of heat that is transmitted to a substrate M per unit time from each micromirror MI, it is possible to maintain the On state of the micromirrors MI for a long time and maintain the Off state for a short time. In order to decrease the amount of heat that is transmitted to a substrate per unit time from each micromirror MI, it is possible to maintain the On state of the micromirrors MI for a short time and maintain the Off state for a long time.

The light L modulated by the light modulation unit 640 and adjusted by the imaging unit 650 is emitted to a substrate M. Each laser emission module 600 can emit light L to a substrate M and a plurality of laser emission modules 600 of a laser emission assembly 500 can simultaneously emit light L to a substrate M.

The laser emission assembly 500 may further include an actuating unit (not shown) that can move between a standby position and a position where light L is emitted to a substrate M supported on the supporting unit 420.

FIG. 12 shows an emission region formed on a substrate when a laser emission assembly emits light to the substrate of FIG. 2.

Referring to FIG. 12, that is, the entire region of a substrate M that needs to be heated may be divided into a plurality of regions. In FIG. 12 and the later figures, for the convenience, the region inside reference marks AK is shown as the entire region of a substrate M that needs to be heated and the components of a substrate M shown in FIG. 2 are not shown. As shown in FIG. 12, the entire region of a substrate M that needs to be heated may be divided into a plurality of unit emission areas UA. The laser emission modules 600 may be arranged to emit light L to corresponding unit emission regions UA, respectively.

Hereafter, various embodiments of the laser emission assembly 500 according to arrangement of a plurality of laser emission modules 600 are described.

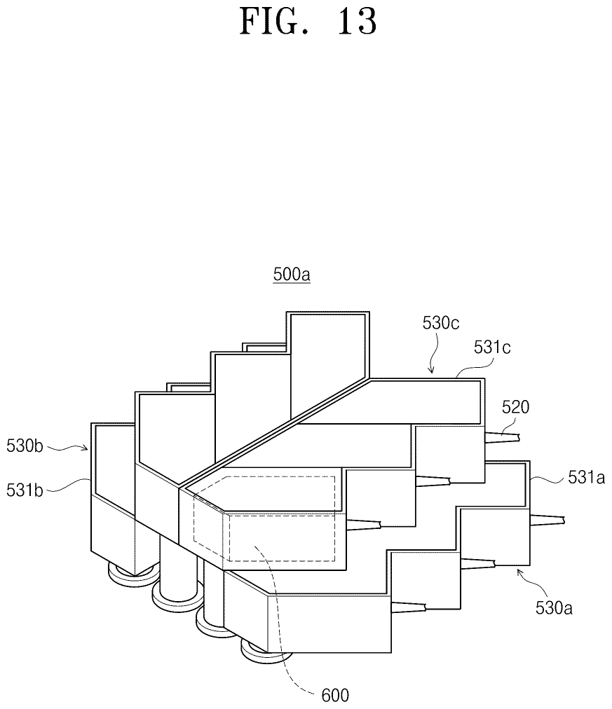

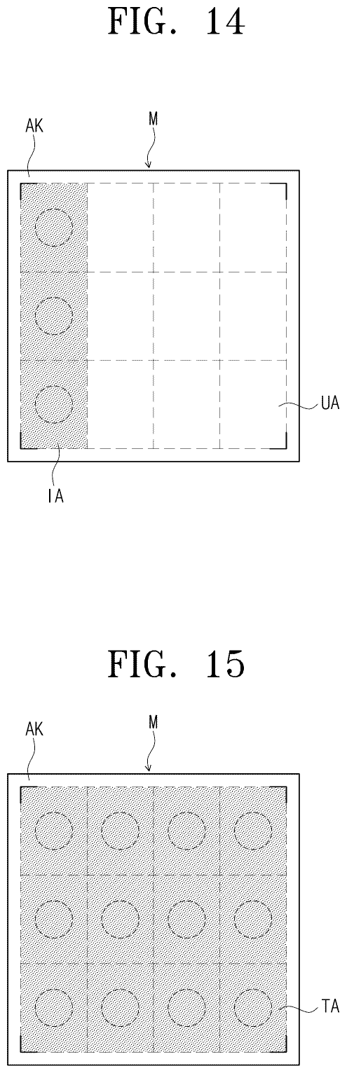

FIG. 13 is a perspective view showing the appearance of a laser emission assembly according to an embodiment of the present disclosure.

Referring to FIG. 13, a laser emission assembly 500a according to an embodiment of the present disclosure includes a first emission module 530a, a second emission module 530b, and a third emission module 530c.

The third emission module 530c is disposed in the center region of the laser emission assembly 500a, and the first emission module 530a is disposed in an edge region and the second emission module 530b is disposed in another edge region with the third emission module 530c therebetween. The third emission module 530c may be disposed at a height different from the first emission module 530a and the second emission module 530b. As shown in FIG. 13, the third emission module 530c may be disposed higher the first emission module 530a and the second emission module 530b.

The emission modules 530a, 530b, and 530c emit light L to a substrate M. Laser emission modules 600 included in the emission modules 530a, 530b, and 530c emit light L to corresponding unit emission regions UA, respectively. The emission modules 530a, 530b, and 530c each may include a frame 531.

Hereafter, the first emission module 530a is described.

The first emission module 530a includes a plurality of laser emission modules 600 and a frame 531a. For example, the first emission modules 530a each include three laser emission modules 600 and a frame 531a surrounding the laser emission modules 600.

The frame 531a may be an outer wall surrounding a plurality of laser emission modules 600. The frame 531a surrounds all of a plurality of laser emission modules 600 and may surround light modulation units 640 disposed at the plurality of laser emission modules 600, respectively.

The plurality of laser emission modules 600 of the first emission module 530a is arranged to emit light to corresponding unit emission regions UA, respectively. The plurality of laser emission modules 600 may be continuously arranged such that the unit emission regions UA corresponding to the first emission module 530a form an emission region IA by continuing in a line.

FIG. 14 shows an emission region to which light is emitted on a substrate by the first emission module of FIG. 13. Referring to FIG. 14, the emission region IA corresponding to the first emission module 530a is formed by sequential unit emission regions UA in a line.

An emission lens 652 of the laser emission module 600 corresponding to the unit emission region UA is projected and shown in each unit emission region UA.

The second emission module 530b and the third emission module 530c each include a plurality of laser emission modules 600 and a frame 531b, 531c.

The third emission module 530c includes a plurality of laser emission modules 600 and a frame 531c. For example, the third emission module 530c includes three laser emission modules 600 disposed on a two rows and a frame 531c surrounding all of the laser emission modules 600. The plurality of laser emission modules 600 of the third emission module 530c is arranged to emit light to corresponding unit emission regions UA, respectively. Description of the other components of the second emission module 530b and the third emission module 530c is replaced by the description of the first emission module 530a.

The emission regions IA corresponding to the emission modules 530a, 530b, and 530c, respectively, are formed by continuously forming unit emission regions UA in a line. FIG. 14 shows an emission region to which light is emitted on a substrate by the first emission module of FIG. 13. Referring to FIG. 14, the emission region IA shown in the left one line on a substrate M is an emission region IA corresponding to the first emission module 530a. The position of an emission lens 652 of the laser emission module 600 corresponding to the unit emission region UA is projected and shown by a circular dotted line in each unit emission region UA.

Referring to FIG. 15, emission regions IA are continuously arranged in a plurality of rows, thereby forming an entire emission region TA. For example, in FIG. 15, the emission region IA shown in the left one line is an emission region corresponding to the first emission module 530a, the emission regions IA shown in the second and third rows are emission regions corresponding to the third emission module 530c, and the emission region IA shown in the fourth line is an emission region corresponding to the second emission module 530b. The entire emission region TA formed by combining the emission regions IA is the same as the entire region of the substrate M, that is, the entire region that needs to be heated on the substrate M.

Referring to FIG. 13 to FIG. 15, as described above, the emission modules 530a, 530b, and 530c are each configured by arranging a plurality of laser emission modules 600 so that emission modules UA can form an emission region IA by continuing in a line.

Further, the emission modules 530a, 530b, and 530c are arranged in parallel such that corresponding emission regions IA are continued such that emission regions IA can form an entire emission region TA by continuing in a plurality of lines. When the sizes of the emission modules 530a, 530b, and 530c are larger that the sizes of the corresponding emission regions IA, the frames 531 of the emission modules 530a, 530b, and 530c may partially overlap each other to continuously form emission regions IA, and the emission modules 530a, 530b, and 530c may be configured with different heights and combined. For example, as shown in FIG. 13, the third emission module 530c may be disposed higher than the first emission module 530a and the second emission module 530b, and the frame 531c of the third emission module 530c may partially overlap the frame 531a of the first emission module 530a and the frame 531b of the second emission module 530b.

Due to the limitation in physical property of the light modulation device 642 included in each of the laser emission modules 600, output of light L that is input to the light modulation device 642 is limited so that the light modulation device 642 is appropriately driven without being damaged. When it is required to heat a substrate with a large amount of heat per unit area or emit high-power light L, the emission area of the light L decreases and it is required to sequentially emit light to partial regions for the entire region of the substrate that needs to be heated, so there is a problem of an increase of the process time.

However, as in the embodiment of the present disclosure, in order that the laser emission assembly 500a can emit light L to the entire region of a substrate M, the emission modules 530a, 530b, and 530c are disposed and emission regions IA form the entire emission region TA by being continuously arranged in a plurality of lines, so it is possible to simultaneously emit light L to the entire region of a substrate M.

Accordingly, it is possible to simultaneously emit light L to the entire region of a substrate M that needs to be heated, it is possible to simultaneously heat the entire region of a substrate M that needs to be heated, and it is possible to effectively adjust the critical dimension of the pattern formed on the substrate M, so it is possible to effectively process the substrate M.

Since the entire region of a substrate M is simultaneously heated, it is not required to move the laser emission assembly 500a in the heating process, so it is possible to reduce the time for moving the laser emission assembly 500a.

In the embodiment described above, when the third emission module 530c is disposed at a height different from the first emission module 530a and the second emission module 530b, there is a problem that the height at which light L is emitted to a substrate M from the laser emission modules 600 of the third emission module 530c is different from the heights at which light L is emitted to the light from the first emission module 530a and the second emission module 530b. In order to solve this problem, the laser emission modules 600 of the third emission module 530c can emit light L at the same height as the first emission module 530a and the second emission module 530b by adjusting the length and configuration of the imaging unit 650.

In the embodiment described above, the emission modules 530a, 530b, and 530c and the laser emission assembly 500a are configured such that the unit emission regions UA of the laser emission modules 600 are arranged in 3×4 to form an entire emission region TA. However, unlike this, the unit emission regions UA may be formed in various shapes and sizes and a plurality of laser emission modules 600 may be appropriately arranged and configured such that the laser emission assembly 500a can emit light L to the entire region of a substrate M.

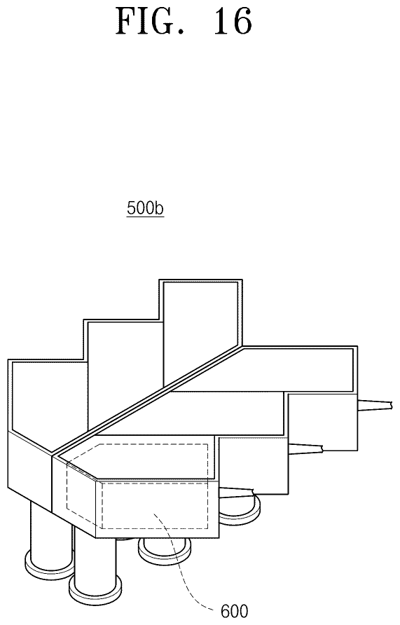

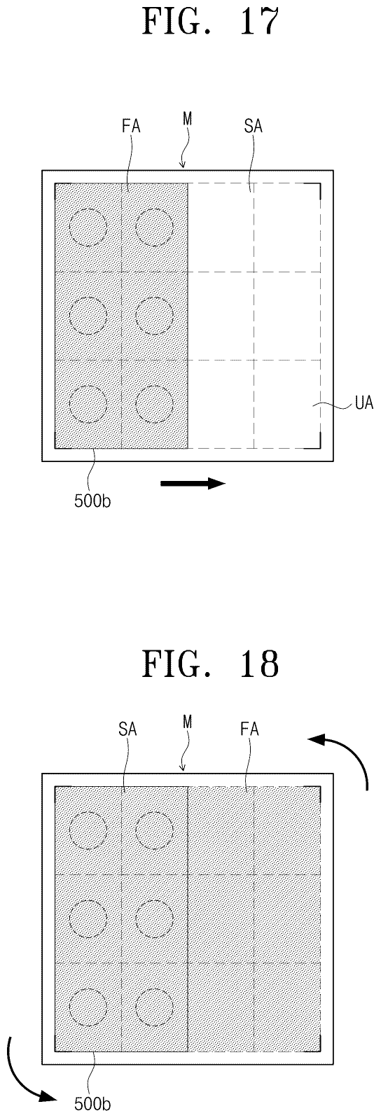

FIG. 16 is a perspective view showing the appearance of a laser emission assembly according to another embodiment of the present disclosure and FIG. 17 shows an emission region to which light is emitted on a substrate by the laser emission assembly of FIG. 16.

Referring to FIG. 16, a laser emission assembly 500b according to an embodiment of the present invention may include a plurality of laser emission modules 600. The laser emission assembly 500b shown in FIG. 16 has a similar configuration to the third emission module 530c shown in FIG. 13. The laser emission assembly 500b includes three laser emission modules 600 arranged in two lines and a frame surrounding all of a plurality of laser emission modules 600. The plurality of laser emission modules 600 is arranged to emit light L to corresponding unit emission regions UA, respectively.

Referring to FIG. 17, unit emission regions UA, which are regions to which light L is emitted on substrate M by the laser emission modules 600 of the laser emission assembly 500b, are arranged in 3×2, thereby being able form a first region FA. The first region FA is a region corresponding to the half of the entire emission region TA. The plurality of laser emission modules 600 included in the laser emission assembly 500b emits light L to unit emission regions UA corresponding thereto, respectively, on a substrate M, whereby the laser emission assembly 500b emits light L to the first region FA. Thereafter, the laser emission assembly 500b is horizontally moved from above the first region FA to over a second region SA. The plurality of laser emission modules 600 included in the laser emission assembly 500b emits light L to unit emission regions UA corresponding thereto, respectively, on a substrate M, whereby the laser emission assembly 500b emits light L to the second region SA. The laser emission assembly 500b may further include an actuating unit not shown to be able to horizontally move with respect to a substrate M or the supporting unit 420 on which a substrate M is supported. The second region SA is a region corresponding to the other half not included in the first region FA in the entire emission region TA. Accordingly, it is possible to emit light L to the entire region TA of the substrate by sequentially emitting light to the first region FA and the second region SA.

In the embodiment of FIG. 17, the laser emission assembly 500b may not be horizontally moved and the supporting unit 420 on which the substrate M is supported may be horizontally moved. The liquid processing chamber 400 may further include an actuating unit not shown and horizontally moving the supporting unit 420 with respect to the laser emission assembly 500b.

According to the embodiment of FIG. 17, any one of the laser emission assembly 500b or the supporting unit 420 is horizontally moved such that the relative positions are switched, whereby it is possible to emit light L to the entire region TA of a substrate M.

FIG. 18 shows another embodiment in which the laser emission assembly of FIG. 16 emits light to a substrate. Referring to FIG. 18, the laser emission assembly 500b can emit light L to the first region FA and then the supporting unit 420 on which the substrate M is supported can be rotated 180° without horizontally moving the laser emission assembly 500b. Accordingly, the region of the substrate disposed under the laser emission assembly 500b to correspond to the emission region of the laser emission assembly 500b can be changed from the first region FA to the second region SA. By rotation of the supporting unit 420, the plurality of laser emission modules 600 of the laser emission assembly 500b sequentially emits light to the first region FA and the second region SA, whereby it is possible to emit light L to the entire region TA of the substrate M.

In the embodiment described above, the unit emission regions UA of the laser emission modules 600 are arranged in 3×2 and the laser emission assembly 500b is configured to be able to emit light L to a region corresponding to the half of the entire emission region TA. However, unlike this, the unit emission regions UA may be formed in various shapes and sizes and a plurality of laser emission modules 600 may be appropriately arranged and configured such that the laser emission assembly 500b can emit light L to a region corresponding to the half of the entire emission region TA.

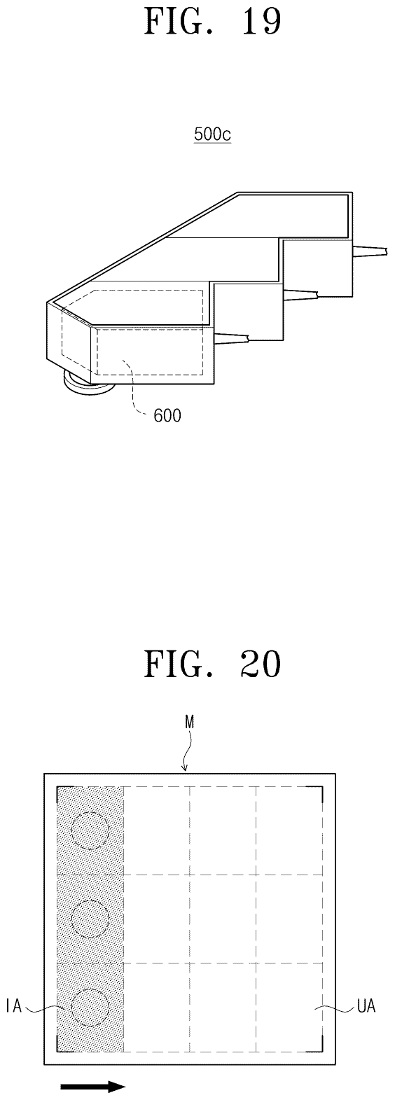

FIG. 19 is a perspective view showing the appearance of a laser emission assembly according to another embodiment of the present disclosure and FIG. 20 shows an emission region to which light is emitted on a substrate by the laser emission assembly of FIG. 19.

Referring to FIG. 19, a laser emission assembly 500c according to an embodiment of the present invention may include a plurality of laser emission modules 600. The laser emission assembly 500c shown in FIG. 19 has a similar configuration to the first emission module 530a or the second emission module 530b shown in FIG. 13. The laser emission assembly 500c includes three laser emission modules 600 arranged in one line and a frame surrounding all of a plurality of laser emission modules 600.

Referring to FIG. 20, a plurality of laser emission modules 600 is arranged to emit light L to corresponding unit emission regions UA, respectively. The unit emission regions UA that are regions to which the laser emission modules 600 emit light L are arranged in 3×1, thereby being able to form one emission line. The plurality of laser emission modules 600 included in the laser emission assembly 500c emits light L to corresponding regions, respectively, of a substrate M. Thereafter, the laser emission assembly 500c is horizontally moved. The laser emission assembly 500c may further include an actuating unit not shown to be able to move with respect to a substrate M. The plurality of laser emission modules 600 included in the laser emission assembly 500c emits light L to corresponding regions, respectively, of a substrate while horizontally moving, whereby it is possible to emit light L to the entire region TA of the substrate M.

In the embodiment of FIG. 20, the laser emission assembly 500c may not be horizontally moved and the supporting unit 420 on which the substrate M is supported may be horizontally moved. The liquid processing chamber 400 may further include an actuating unit not shown such that the supporting unit 420 can be horizontally moved with respect to the laser emission assembly 500c.

According to the embodiment of FIG. 20, any one of the laser emission assembly 500c or the supporting unit 420 is horizontally moved such that the relative positions are switched, whereby it is possible to emit light L to the entire region TA of a substrate M.

In the embodiment described above, the unit emission regions UA of the laser emission modules 600 are arranged in 3×1 and the laser emission assembly 500c is configured to be able to emit light L to a region corresponding to a quarter of the entire emission region TA. However, unlike this, the unit emission regions UA may be formed in various shapes and sizes and a plurality of laser emission modules 600 may be appropriately arranged and configured such that the laser emission assembly 500c can emit light L to the entire emission region TA of a substrate M by horizontally moving.

In the embodiments described above, since a plurality of laser emission modules 600 is combined, it is possible to simultaneously emit light L to a plurality of unit emission regions UA, so it is possible to simultaneously emit light L to a wide region of a substrate M that needs to be heated and it is possible to effectively adjust the critical dimension of the pattern formed on the substrate M, whereby it is possible to effectively process the substrate M.

It is exemplified in the embodiments described above that laser emission modules 600 are arranged in 3×n, thereby configuring the laser emission assembly 500. However, unlike this, the laser emission modules 600 may be disposed in various arrays in the laser emission assembly 500 in accordance with the size of a substrate M and the size of unit emission regions UA, whereby it is possible to simultaneously emit light L to a wide region of a substrate M that needs to be heated.

In the embodiments described above, it was described that light L generated from one laser source 510 is transmitted to one laser emission module 600 through the laser transmission member 510. According to this, the output range of light L that is generated is limited in the laser source 510 such that the light modulation device 642 is appropriately driven without being damaged. Further, the laser source 510 is needed as much as the number of the laser emission modules 600. In order to solve these problems, another embodiment in which the laser source 510 and the laser transmission member 520 of the present invention transmit light L to the laser emission modules 600 is described.

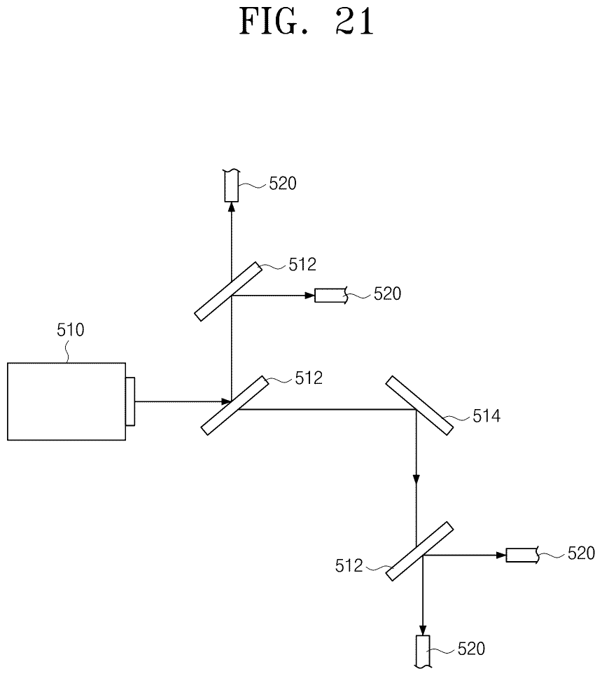

FIG. 21 briefly shows a configuration in which a laser source and a laser transmission member transmit light to a laser emission module in accordance with another embodiment of the present invention.

Referring to FIG. 21, light L is output from one laser source 510. The output light Lis transmitted to a plurality of laser transmission members 520 through a plurality of splitters 512 and a reflective mirror 514. In this process, the power of the light L output from the laser source 510 is distributed. As shown in FIG. 21, one laser source 510 can output high-power light L and distribute and transmit the light L to the laser transmission members 520. Accordingly, even though the laser source 510 generates high-power light L, light L with low power distributed through the splitters 512 is transmitted to the laser emission module 600, so it is possible to minimize the problem that the power of the laser source 510 is limited.

It was described in the embodiments described above that the laser emission assembly 500 may further include an actuating unit (not shown) that can move between a standby position and a position where light L is emitted to a substrate M supported on the supporting unit 420, but, unlike this, the laser emission assembly 500 may be fixedly installed to the liquid processing chamber 400 and can emit light L to a substrate M supported on the supporting unit 420.

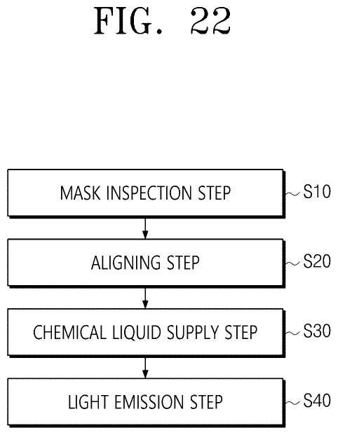

FIG. 22 is a flowchart showing a substrate processing method according to an embodiment of the present disclosure. The substrate processing method according to an embodiment of the present disclosure may be a mask processing method that processes a mask. The substrate processing method to be described below may be performed by controlling the components of the substrate processing apparatus by means of the control unit 30.

Referring to FIG. 2, FIG. 3, and FIG. 22, the substrate processing method according to an embodiment of the present invention may include a mask inspection step S10, an aligning step S20, chemical liquid supply step S30, and a light emission step S40.

In the mask inspection step S10, it is possible to inspect the critical dimension of patterns formed on a substrate M. For example, in the mask inspection step S10, it is possible to inspect the critical dimensions of a first pattern P1, a second pattern P2, and exposure patterns EP formed on a substrate M. In the mask inspection step S10, it is possible to specify patterns that require adjustment of critical dimension of pattern of the first pattern P1, the second pattern P2, and the exposure patterns EP formed on the substrate M. In the mask inspection step S10, it is possible to specify regions to which light needs to be emitted on the substrate M. The mask inspection step S10 may be performed by photographing the substrate M using a vision sensor such as a camera. The mask inspection step S10 may be performed in an inspection chamber (not shown) of the substrate processing apparatus of the present invention or may be performed in a separate inspection chamber provided outside the substrate processing apparatus. In the mask inspection step S10, regions that require adjustment of critical dimensions of pattern (i.e., regions that need to be heated by light L) on the substrate M through vision inspection can be mapped. The mapping data of the critical dimension adjustment-requiring regions mapped in the mask inspection step S10 may include the positions and sizes of the critical dimension adjustment-requiring regions on the substrate M, critical dimension information of pattern, etc. The control unit 30 may store the mapping data.

In the aligning step S20, alignment of the position and direction of the substrate M and alignment of the emission position of light L that is emitted by the laser emission assembly 500 can be performed.

First, alignment of the position and direction of the substrate M can be performed using an alignment marks AK formed on the substrate M. For example, it is possible to photograph the substrate M using a vision sensor such as a camera (not shown) of the liquid processing chamber 400 and it is possible to check and align the position where the substrate M is placed on the supporting unit 420 and the direction of the substrate M through the alignment marks AK formed on the substrate M. For example, when the position of the substrate M departs, the position of the substrate M can be aligned by the transfer robot 320. Further, when the position of the substrate M departs, the laser emission assembly 500 can emit light L while reflecting the departing position. Further, when the position of the substrate M departs, the supporting unit 320 can align the direction of the substrate M by rotating the substrate M.

In the chemical liquid supply step S30, it is possible to supply chemical liquid C to the substrate M. In the chemical liquid supply step S30, it is possible to supply chemical liquid C while rotating the substrate M, and unlike, it is also possible to supply chemical liquid C without rotating the substrate M. The chemical liquid C that is supplied in the chemical liquid supply step S30 may be an etching solution. The chemical liquid C may be referred to as an etchant. When the chemical liquid supply step S30 is finished, a liquid film by the chemical liquid C can be formed on the substrate M. In the chemical liquid supply step S30, the supporting unit 40 may rotate the substrate M or may support the substrate M without rotating the substrate to prevent the substrate M from being misaligned.

In the light emission step S40, it is possible to heat a specific region of the substrate M by emitting light to the top surface of the substrate M with the liquid film formed by the chemical liquid C. The entire pattern on the substrate M is etched by chemical liquid and the specific region to which light L is emitted can be more etched because it is heated. The degree of etching depends on the amount of heat transmitted by light L per unit time and the light modulation unit 640 of the present invention can form emission patterns having various shapes, so it is possible to control etching for a substrate M in various ways. In the light emission step S40, the supporting unit 420 can support the substrate M without rotating it.

In the example described above, it was exemplarily described that the substrate M that is processed in the liquid processing chamber 400 is a photomask that is a ‘frame’ that is used in an exposure process, but the present invention is not limited thereto. For example, a substrate may be various kinds of substrates that require etching or adjustment of critical dimension of pattern such as a wafer and a glass substrate.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

What is claimed is:

1. A substrate processing apparatus comprising:
a supporting unit supporting a substrate; and
a laser emission assembly emitting a laser to the substrate,
wherein the laser emission assembly comprises:
a laser source generating a laser; and
a plurality of laser emission modules,
the laser emission modules each comprise:
a light modulation unit modulating distribution of a laser generated by the laser source; and
an imaging unit adjusting and emitting the laser modulated by the light modulation unit to the substrate to correspond to an area to which the laser is emitted,
an entire region that needs to be heated on the substrate is composed of a plurality of unit emission regions, and
the plurality of laser emission modules are arranged to be able to emit the laser respectively to the different unit emission regions of the substrate supported on the supporting unit.

2. The substrate processing apparatus of claim 1, wherein the laser emission assembly is configured by arranging the plurality of laser emission modules such that the unit emission regions respectively corresponding to the plurality of laser emission modules are continued in a line to form an emission region.

3. The substrate processing apparatus of claim 2, wherein the laser emission assembly is configured by arranging the plurality of laser emission modules such that the emission regions are continued in one or more lines to form an entire emission region.

4. The substrate processing apparatus of claim 3, wherein the entire emission region to which the laser is emitted on the substrate from the laser emission assembly is the entire region that needs to be heated on the substrate.

5. The substrate processing apparatus of claim 4, wherein the laser emission assembly further comprises a control unit, and
the control unit controls the laser emission assembly to emit the laser to the entire region of the substrate by emitting the laser to corresponding unit emission regions through the plurality of laser emission modules, respectively.

6. The substrate processing apparatus of claim 4, wherein the laser emission assembly comprises:
a first emission module disposed in an edge region and comprising one or more of the laser emission module;
a second emission module disposed in another edge region and comprising one or more of the laser emission module; and
a third emission module disposed in a center region and comprising one or more of the laser emission module, and
the third emission module is disposed at a height different from the first emission module and the second emission module.

7. The substrate processing apparatus of claim 6, wherein the first emission module, the second emission module, and the third emission module each have a frame surrounding the light modulation unit, and
the frame of the third emission module and the frame of the first emission module or the second emission module partially overlap each other when seen from above.

8. The substrate processing apparatus of claim 3, wherein the laser emission assembly further comprises a control unit, and
the control unit performs control such that
the plurality of laser emission modules emit the laser to corresponding unit emission regions, respectively, on the substrate,
relative positions of the substrate supported on the supporting unit and the laser emission modules are changed by horizontally moving any one of the supporting unit and the laser emission assembly, and
the plurality of laser emission modules can emit the laser to the entire region of the substrate through the horizontal movement.

9. The substrate processing apparatus of claim 3, wherein the laser emission assembly further comprises: an actuator rotating the supporting unit; and
a control unit,
wherein the control unit performs control such that the laser emission assembly emits the laser to a first region of the substrate by emitting the laser to corresponding unit emission regions of the substrate through the plurality of laser emission modules, respectively, and such that the laser emission assembly emits the laser to a second region on the substrate by rotating the supporting unit,
the first region and the second region are each a region corresponding to a half of the entire region of the substrate, and
the plurality of laser emission modules can emit the laser to the entire region of the substrate through the rotation.

10. The substrate processing apparatus of claim 1, further comprising: a liquid supply unit supplying liquid to a substrate supported on the supporting unit.

11. The substrate processing apparatus of claim 1, wherein the laser emission assembly further comprises a laser transmission member transmitting the laser generated by the laser source to the laser emission modules.

12. The substrate processing apparatus of claim 11, wherein the laser emission assembly further comprises a beam splitter splitting the laser generated by the laser source, and
the laser split by the beam splitter is transmitted to the laser emission modules through the laser transmission member.

13. The substrate processing apparatus of claim 11, wherein the laser emission assembly further comprises a beam shaper converting the type of the laser generated by the laser source, and
the beam shaper changes the type of the laser transmitted through the laser transmission member and transmits the laser with the changed type to the light modulation unit.

14. The substrate processing apparatus of claim 1, wherein the substrate is a photomask or a wafer.

15. The substrate processing apparatus of claim 1, wherein the light modulation unit further comprises a Digital Micro-mirror Device (DMD) that is a light modulation device, and
the DMD comprises:
micromirrors provided to be rotatable; and
a board substrate on which the micromirrors are installed.

16. A substrate processing apparatus comprising:
a supporting unit supporting a substrate; and
a laser emission assembly emitting a laser to the substrate,
wherein the laser emission assembly comprises:
a laser source generating a laser;
a plurality of laser emission modules; and
a laser transmission member transmitting the laser generated by the laser source to the laser emission modules,
wherein the laser emission modules each comprise:
a Digital Micro-mirror Device (DMD) unit modulating distribution of the laser generated by the laser source; and
an imaging unit adjusting and emitting the laser modulated by the DMD to the substrate to correspond to an area to which the laser is emitted,
wherein the DMD comprises:
micromirrors provided to be rotatable; and
a device substrate on which the micromirrors are installed,
an entire region that needs to be heated on the substrate is composed of a plurality of unit emission regions, and
the plurality of laser emission modules are arranged to be able to emit the laser respectively to the different unit emission regions of the substrate supported on the supporting unit.

17. The substrate processing apparatus of claim 16, wherein the laser emission assembly is configured by arranging the plurality of laser emission modules such that the unit emission regions respectively corresponding to the plurality of laser emission modules are continued in a line to form an emission region and the emission regions are continued in one or more lines to form an entire emission region.

18. The substrate processing apparatus of claim 17, wherein the laser emission assembly comprises:
a first emission module disposed in an edge region and comprising one or more of the laser emission module;
a second emission module disposed in another edge region and comprising one or more of the laser emission module; and
a third emission module disposed in a center region and comprising one or more of the laser emission module,
the third emission module is disposed at a height different from the first emission module and the second emission module, and
the laser emission assembly is controlled to emit the laser to the entire region of the substrate by emitting the laser to corresponding emission regions through the first emission module, the second emission module, and the third emission module, respectively.

19. A substrate processing apparatus comprising:
a supporting unit supporting a substrate;
a laser emission assembly emitting a laser to the substrate; and
a control unit,
wherein the laser emission assembly comprises:
a laser source generating a laser;
a plurality of laser emission modules; and
a laser transmission member transmitting the laser generated by the laser source to the laser emission modules,
wherein the laser emission modules each comprise:
a Digital Micro-mirror Device (DMD) unit modulating distribution of the laser generated by the laser source; and
an imaging unit adjusting and emitting the laser modulated by the DMD to the substrate to correspond to an area to which the laser is emitted,
wherein the DMD comprises:
micromirrors provided to be rotatable; and
a device substrate on which the micromirrors are installed,
an entire region that needs to be heated on the substrate is composed of a plurality of unit emission regions,
the plurality of laser emission modules are arranged to be able to emit the laser respectively to the different unit emission regions of the substrate supported on the supporting unit,
the unit emission regions respectively corresponding to the plurality of laser emission modules are continued in a line to form an emission region,
the emission regions are continued in one or more lines to form an entire emission region,
the entire emission region is the entire region that needs to be heated on the substrate, and
the control unit controls the laser emission assembly to emit the laser to the entire region of the substrate by emitting the laser to corresponding unit emission regions through the plurality of laser emission modules, respectively.

20. The substrate processing apparatus of claim 19, wherein the laser emission assembly comprises:
a first emission module disposed in an edge region and comprising one or more of the laser emission module;
a second emission module disposed in another edge region and comprising one or more of the laser emission module; and
a third emission module disposed in a center region and comprising one or more of the laser emission module,
the third emission module is disposed at a height different from the first emission module and the second emission module.
